(19) United States
(12) Patent Application Publication
(10) Pub. No.: US 2014/0118004 A1
(43) Pub. Date: May 1, 2014

(54) Measurement Structure for Radio Frequency Scattering Parameter Measurement Applying Two Calibrators and Calibration Method Thereof

(71) Applicant: YUAN ZE UNIVERSITY, Taoyuan County (TW)

(72) Inventor: Chien-Chang HUANG, Taoyuan County (TW)

(73) Assignee: YUAN ZE UNIVERSITY, Taoyuan County (TW)

(21) Appl. No.: 13/664,002

(22) Filed: Oct. 30, 2012

(51) Int. Cl. G01R 35/00

(52) U.S. Cl. 324/601

(57) ABSTRACT

The present invention provides a measurement structure for radio frequency (RF) scattering parameter measurement applying two calibrators and a calibration method thereof, comprising an offset series device calibrator, an offset shunt device calibrator and a tested object measuring instrument. Herein the lengths of the transmission lines for the offset series device calibrator and the offset shunt device calibrator and the one of the transmission line for the tested object measuring instrument are equivalent such that the offset series device calibrator, the offset shunt device calibrator and the tested object measuring instrument have the identical error box. After having acquired the scattering parameter matrix for the error box through the calibration method, it is possible to connect a tested electronic device onto the tested object measuring instrument and perform operations on the uncorrected measurement data thereby obtaining the RF scattering parameters of the tested object.

### BACKGROUND OF THE INVENTION

1. Field of the Invention

The present invention generally relates to a measurement structure for radio frequency (RF) scattering parameter measurement applying two calibrators and a calibration method thereof; in particular, the present invention is addressed to a measurement structure and a calibration method thereof capable of, especially with regards to one-tier semiconductor wafer components or other substrate components, analyzing the influence of the transmission line characteristic impedance on a tested object and performing the de-embedment process to the RF scattering parameter measurement, and the calibration method thereof.

2. Description of Related Art

Typically, it is difficult to directly measure the voltage and current of a signal in the radio frequency microwave frequency band, thus in such a frequency band, it is necessary to discuss in the form of wave with actions through incidence, reflection and absorption thereby facilitating measurements of scattering parameters thereof. Because the entire measurement system needs to perform a sequence of complicated processes, the measurement calibration is consequently required in order to improve the accuracy of measurements, in which the measurement error can be mathematically characterized by using an error matrix, and the measurement error can be roughly divided into three major categories; i.e., random, drift and system errors, among which the scattering parameter of the system error can be effectively detected by a network analyzer under a stable measurement environment, further obtaining the error thereof, thus completing the measurement calibration.

In practice, the implementation procedure for such a calibration method is essentially to adjust the initial status of the instrument after startup to a user-defined actual measurement environment so as to eliminate any additional errors other than the tested object; while currently available radio frequency scattering parameter measurement for semiconductor wafer devices typically operates in a two-tier approach, comprising the following steps:

1. performing calibrations on the system before starting the measurement thereby eliminating the effect caused by the measuring instrument and environment; hence it first uses a probe in conjunction with an Impedance Standard Substrate (ISS) for calibration, whose calibration method can be SOLT (Short-Open-Load-Thru) or LRM (Line-Reflect-Match), and then moves the measurement reference plane to the tip of the probe, but a small segment of connecting line exists between the probe pad and the tested device within the wafer, and the capacitive effect in the probe pad of large area may not be effectively calibrated;

2. further performing calibrations on the additional dummy structure (e.g., Short, Open, Thru etc.) of the wafer so as to remove the effects caused by the pad and the connecting line, i.e., the de-embedding procedure, thus the major purpose of de-embedding is to remove the effect of the test clamping fixture from the measurement data in raw test results so as to acquire the most primitive characterization of the device.

However, such a two-tier measurement approach has the following drawbacks:

1. the high frequency feature of the additional dummy structure on the wafer may not be conveniently appreciated, and in case it is assumed to be an ideal feature, significant errors may be undesirably introduced at high frequency in the de-embedding process;

2. the two-tier measurement consumes much the wafer probe test time, consequently, as applying to massive tests, it becomes comparatively critical;

3. since the Impedance Standard Substrate (ISS) is expensive and the feature thereof may degrade after each test due to scratches on its pad caused by the probe, the substrate needs to be replaced after a certain cycles of use, thus adversely elevating the test cost.

Regarding to the aforementioned drawbacks, some literatures have proposed certain solutions therefore, including:
1. IEEE Trans. Electron Devices, vol. 54, no. 10, pp. 2706-2714, October 2007, describing the use of a one-tier measurement for de-embedding operation at the cost of five dummy structures (Open, Short, Thai, Left, Right), so the precision thereof may be compromised in comparison with the two-tier approach.
2. IEEE Trans. Microwave Theory Tech., vol. 51, pp. 2391-2401, December 2003, describing a Multiline Thru-Reflect-Line (TRL) calibration method developed by NIST (National Institute of Standards and Technology), which enables completion of calibration and de-embedding process in a one-tier fashion, but presents a disadvantage of requirement on multiple transmission line segments which significantly occupies valuable wafer area.

Moreover, the National Institute of Standards and Technology (NIST) in United States has developed the standard line length and line width for the transmission line of 50Ω, and all designed transmission lines can be compared in accordance with the standard transmission line, and then the characteristic impedance thereof can be calculated through mathematical operations. This approach indeed eliminated certain limitations resulting from the requirement on the substrate of low losses, but it needs to refer to the NIST to make comparisons for each design, and thus inconvenience may so occur.

Hence, it would be an optimal solution to provide a measurement structure for radio frequency (RF) scattering parameter measurement applying two calibrators and a calibration method thereof which can perform the de-embedding process in a one-tier radio frequency scattering parameter measurement of semiconductor wafer devices or other substrate devices without using the Impedance Standard Substrate but requiring the solution of simply three variables in mathematical operations.

### SUMMARY OF THE INVENTION

The objective of the present invention is to provide a measurement structure for radio frequency (RF) scattering parameter measurement applying two calibrators and a calibration method thereof which uses a one-tier measurement for the de-embedding process and also spontaneously figures out the characteristic impedance of the transmission line.

Another objective of the present invention is to provide a measurement structure for radio frequency (RF) scattering parameter measurement applying two calibrators and a calibration method thereof which needs only two calibrators to accomplish broadband measurements, and also uses the known conditions offered by the calibrators to solve the same or more numbers of unknown variables in order to successfully complete the self-calibration.

To achieve the aforementioned objectives, a measurement structure for radio frequency (RF) scattering parameter measurement applying two calibrators and a calibration method thereof herein is provided, which uses a microwave probe as the contact interface for microwave signal transmissions, wherein the microwave probe at least includes a ground and a signal end, and the measurement structure for radio frequency scattering parameter measurement applying two calibrators comprises: an offset series device calibrator, in which the microwave probe contacts the offset series device calibrator, and the offset series device calibrator consists of two transmission lines, an offset transmission line and a series resistor, in which the offset transmission line and the series resistor are connected between the two transmission lines, and the transmission lines are connected to the signal end of the microwave probe thereby performing measurements on the device characteristics of the series resistor; an offset shunt device calibrator, in which the microwave probe contacts the offset shunt device calibrator, and the offset shunt device calibrator consists of two transmission lines, an offset transmission line and a shunt resistor, in which the offset transmission line and the shunt resistor are connected between the two transmission lines, and the transmission lines are connected to the signal end of the microwave probe thereby performing measurements on the device characteristics of the shunt resistor; and a tested object measuring instrument, in which the microwave probe contacts the tested object measuring instrument, and the tested object measuring instrument consists of two transmission lines and a tested object, in which the tested object is connected between the two transmission lines and the transmission lines are connected to the signal end of the microwave probe thereby performing measurements on the device characteristics of the tested object.

More specifically, the length of the transmission lines for the offset series device calibrator and the offset shunt device calibrator is equal to the one of the transmission line for the tested object measuring instrument.

More specifically, the offset series device calibrator, the offset shunt device calibrator and the tested object measuring instrument are applicable to silicon substrates, compound semiconductor substrates (e.g., GaAs, GaN, InP or the like), ceramic substrates/FR-4 substrates or epoxy glass fiber board substrates.

More specifically, the offset series device calibrator, the offset shunt device calibrator and the tested object measuring instrument can apply the coplanar waveguide or the microstrip as the connection transmission line.

More specifically, the microwave probe is a high frequency probe and the type thereof can be G-S-G-S-G, G-S-S-G, G-S-G or G-S.

In addition, the present invention provides a calibration method for radio frequency scattering parameter measurement applying two calibrators, in which the method uses two calibrators, a tested object measuring instrument and equations of three variables, wherein the two calibrators and the tested object measuring instrument have the identical error boxes and the scattering parameter matrixes of the error boxes can be obtained by the calibration method such that, after connecting a tested electronic device onto the tested object measuring instrument, operations on uncorrected measurement data can be performed thereby obtaining the radio frequency scattering parameter of the tested object.

More specifically, the calibration method for radio frequency scattering parameter measurement enables the self-calibration which is intended to deduct errors introduced during measurements, in which the characteristics of such errors can be expressed with mathematical models, and, after measurements by the offset series device calibrator and the offset shunt device calibrator, all error parameters can be solved, so that, after repetitive operations, the errors required to be calibrated can be obtained through operations, thus further calculating the parameters of the actual tested object.

### BRIEF DESCRIPTION OF THE DRAWINGS

FIG. 1A shows a structure diagram of the coplanar waveguide layout involved in the measurement structure for radio frequency scattering parameter measurement applying two calibrators and a calibration method thereof in accordance with the present invention;

FIG. 1B shows a structure diagram of the microstrip layout involved in the measurement structure for radio frequency scattering parameter measurement applying two calibrators and a calibration method thereof in accordance with the present invention;

FIG. 2 shows an equivalent circuit diagram of the calibrator involved in the measurement structure for radio frequency scattering parameter measurement applying two calibrators and a calibration method thereof in accordance with the present invention;

FIG. 3 shows a flowchart of the calibration operations involved in the measurement structure for radio frequency scattering parameter measurement applying two calibrators and a calibration method thereof in accordance with the present invention; and

FIG. 4 shows a dual-port network architecture diagram of the integral measurements involved in the measurement structure for radio frequency scattering parameter measurement applying two calibrators and a calibration method thereof in accordance with the present invention.

### DETAILED DESCRIPTION OF THE PREFERRED EMBODIMENTS

The aforementioned and other technical contents, aspects and effects in relation with the present invention can be clearly appreciated through the detailed descriptions concerning the preferred embodiments of the present invention in conjunction with the appended drawings.

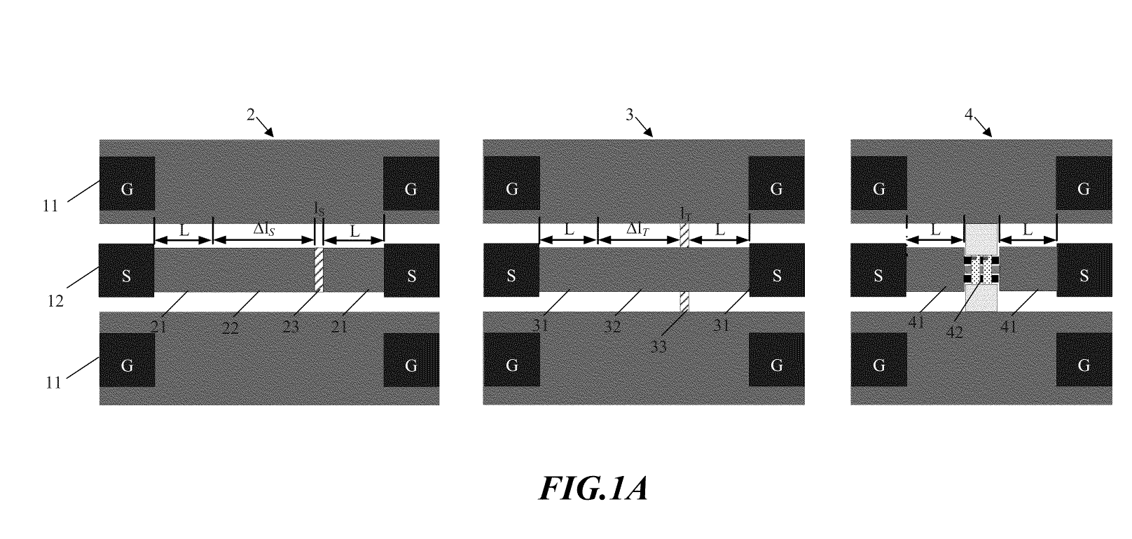

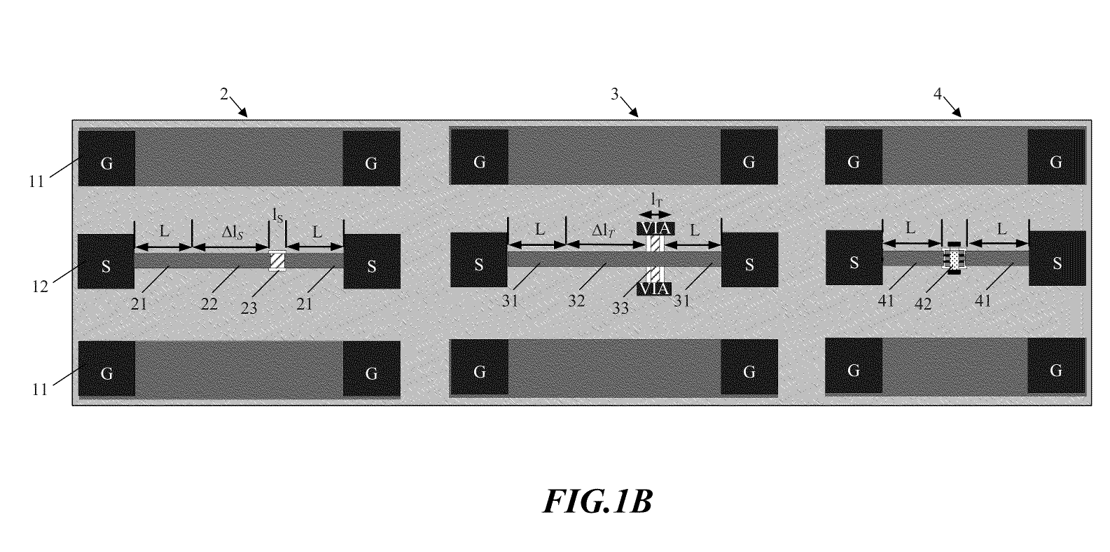

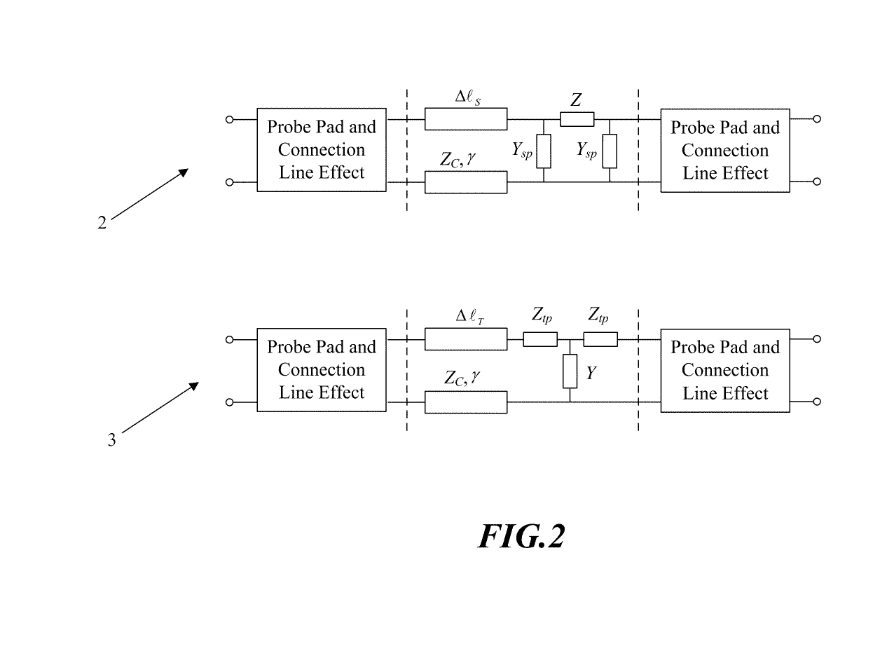

Refer first to FIGS. 1A, 1B and 2, wherein a structure diagram of the coplanar waveguide layout, a structure diagram of the microstrip layout and an equivalent circuit diagram of the calibrator involved in the measurement structure for radio frequency scattering parameter measurement applying two calibrators and a calibration method thereof in accordance with the present invention are respectively shown. From these Figures, it can be appreciated that the illustrated measurement structure for radio frequency scattering parameter measurement uses a microwave probe as the contact interface for microwave signal transmissions, wherein the microwave probe at least includes a ground 11 and a signal end 12, and the measurement structure for radio frequency scattering parameter measurement comprises:

an offset series device calibrator 2, in which the microwave probe (the ground 11 and the signal end 12) contacts the offset series device calibrator 2, and the offset series device calibrator 2 consists of two transmission lines 21, an offset transmission line 22 and a series resistor 23, in which the offset transmission line 22 and the transmission lines 21 have the same width, the offset transmission line 22 is connected to the series resistor 23, the offset transmission line 22 and the series resistor 23 are connected between the two transmission lines 21, and also the transmission lines 21 are connected to the signal end 12 of the microwave probe thereby performing measurements on the device characteristics of the series resistor 23;

an offset shunt device calibrator 3, in which the microwave probe (the ground 11 and the signal end 12) contacts the offset shunt device calibrator 3, and the offset shunt device calibrator 3 consists of two transmission lines 31, an offset transmission line 32 and a shunt resistor 33, in which the offset transmission line 32 and the transmission lines 31 have the same width, the offset transmission line 32 is connected to the shunt resistor 33, the offset transmission line 32 and the shunt resistor 33 are connected between the two transmission lines 31, and also the transmission lines 31 are connected to the signal end 12 of the microwave probe thereby performing measurements on the device characteristics of the shunt resistor 33;

a tested object measuring instrument 4, in which the microwave probe (the ground 11 and the signal end 12) contacts the tested object measuring instrument 4, and the tested object measuring instrument 4 consists of two transmission lines 41 and a tested device 42, in which the tested device 42 is connected between the two transmission lines 41 and the two transmission lines 41 are connected to the signal end 12 of the microwave probe thereby performing measurements on the device characteristics of the tested device 42 (the tested device is shown as an FET device in FIGS. 1A and 1B).

It should be noted that, as shown in FIG. 2, the equation for the equivalent circuit of the offset series device calibrator 2 (where yₛₚ is a high frequency parasitic effect device) includes:

$$z ≡ \frac{Z}{{Z}_{C}} , {y}_{sp} ≡ \frac{{Y}_{sp}}{{Y}_{C}} , {Y}_{C} ≡ \frac{1}{{Z}_{C}} .$$

It should be noted that, as shown in FIG. 2, the equation for the equivalent circuit of the offset shunt device calibrator 3 (where zₜₚ is a high frequency parasitic effect device) includes:

$$y ≡ \frac{Y}{{Y}_{C}} , {z}_{tp} ≡ \frac{{Z}_{tp}}{{Z}_{C}} , {Y}_{C} ≡ \frac{1}{{Z}_{C}} .$$

It should be noted that the transmission lines 21 for the offset series device calibrator 2, the transmission lines 31 for the offset shunt device calibrator 3 and the transmission lines 41 for the tested object measuring instrument 4 have the same length, such that the offset series device calibrator 2, the offset shunt device calibrator 3 and the tested object measuring instrument 4 are characterized in the identical error boxes.

It should be noted that the length of the offset transmission line 22 in the offset series device calibrator 2 may differ from the length of the offset transmission line 32 in the offset shunt device calibrator 3.

It should be noted that the offset series device calibrator 2, the offset shunt device calibrator 3 and the tested object measuring instrument 4 are applicable to silicon substrates, compound semiconductor (GaAs, GaN, InP etc.) substrates or ceramic/FR-4 (epoxy glass fiber board) substrates.

It should be noted that the offset series device calibrator 2, the offset shunt device calibrator 3 and the tested object measuring instrument 4 can use the coplanar waveguide or the microstrip as the connection transmission line, as shown in FIG. 1A, wherein such calibrators (i.e., the offset series device calibrator 2 and the offset shunt device calibrator 3) and the tested object measuring instrument 4 use the coplanar waveguide as the connection transmission line; and alternatively, as shown in FIG. 1B, wherein the calibrators (i.e., the offset series device calibrator 2 and the offset shunt device calibrator 3) and the tested object measuring instrument 4 apply the microstrip as the connection transmission line.

It should be noted that the microwave probe is a high frequency probe and the type thereof can be G-S-G-S-G, G-S-S-G, G-S-G (Ground-Signal-Ground) or G-S (Ground-Signal).

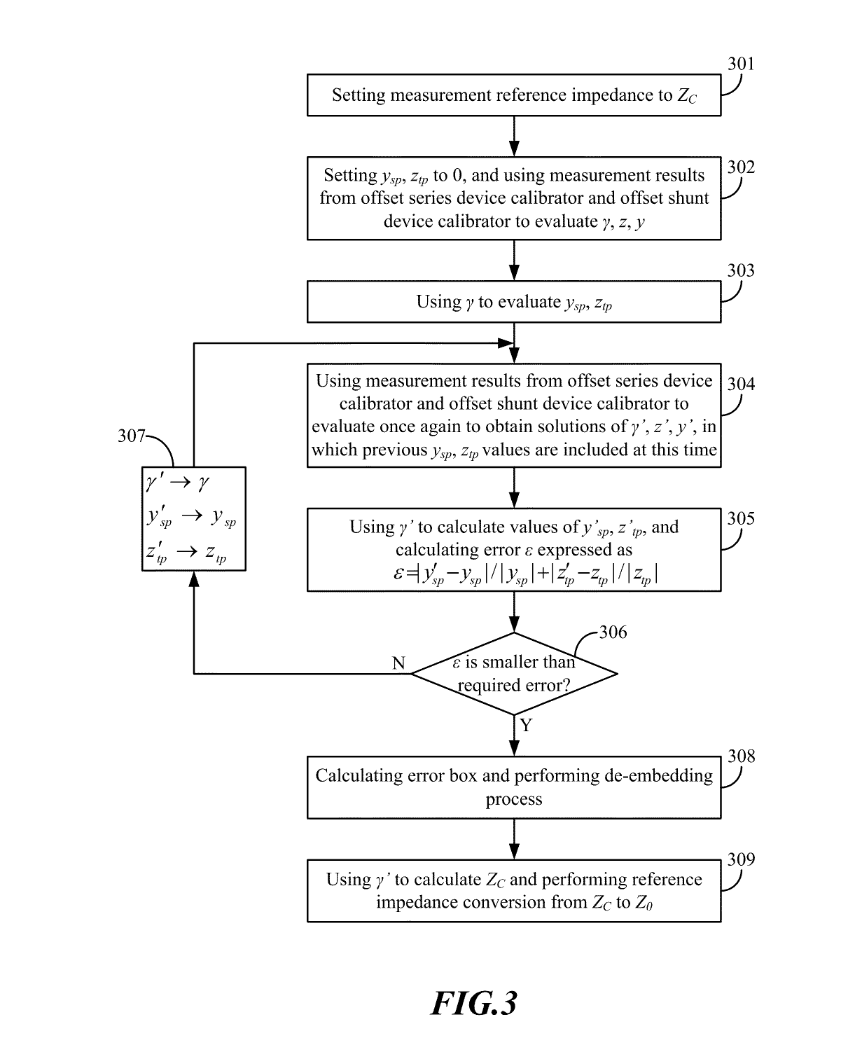

Next, FIG. 3 shows a flowchart of the calibration operations involved in the measurement structure for radio frequency scattering parameter measurement applying two calibrators and a calibration method thereof in accordance with the present invention. For the Figure, it can be seen that it is possible to uses the known conditions offered by the two calibrators to solve the same or more numbers of unknown variables, and the calibration method for RF scattering parameter measurement applying two calibrators according to the present invention comprises the following steps:
1. initially, setting the measurement reference impedance to the transmission line characteristic impedance Z_{C}, and setting a self-calibration equation including multiple variables t(e^{γΔl}^{ₛ}), z, y, zₜₚ, yₛₚ (301) (γ indicates the propagation constant of the transmission line, Δl_{S} the length of the offset transmission line segment in the offset series device calibrator, Δl_{T} the length of the offset transmission line segment in the offset shunt device calibrator, w=Δl_{T}/Δl_{S}, z the standardized impedance of the series device calibrator, y the standardized admittance of the shunt device calibrator, and zₜₚ, yₛₚ the high frequency parasitic effect elements); thus such self-calibration equations can be expressed as below:

$$\begin{matrix}{f}_{1} = - [ {y}_{sp} - \frac{z ( 1 - {y}_{sp}^{2} )}{2} ] [ {z}_{tp} - \frac{y ( 1 - {z}_{tp}^{2} )}{2} ] [ {t}^{( 1 - w )} + {t}^{- ( 1 - w )} ] + [ 1 - {y}_{sp} - \frac{{z ( 1 - {y}_{sp} )}^{2}}{2} ] [ 1 + {z}_{tp} + \frac{{y ( 1 + {z}_{tp} )}^{2}}{2} ] \cdot {t}^{- ( 1 - w )} + [ 1 + {y}_{sp} + \frac{{z ( 1 + {y}_{sp} )}^{2}}{2} ] [ 1 - {z}_{tp} - \frac{{y ( 1 - {z}_{tp} )}^{2}}{2} ] \cdot {t}^{( 1 - w )} - trace ( {[ {M}_{OS , f} ] [ {M}_{OT , f} ]}^{- 1} \} & ( 1 ) \\ {f}_{2} = 2 [ ( 1 - {y}_{sp} ) - \frac{{z ( 1 - {y}_{sp} )}^{2}}{2} ] [ ( 1 + {y}_{sp} ) + \frac{{z ( 1 + {y}_{sp} )}^{2}}{2} ] + {[ {y}_{sp} - \frac{z ( 1 - {y}_{sp}^{2} )}{2} ]}^{2} \cdot [ {t}^{2} + {t}^{- 2} ] - trace \{ {[ {M}_{OS , f} ] [ {M}_{OS , r} ]}^{- 1} \} & ( 2 ) \\ {f}_{3} = 2 [ ( 1 - {z}_{tp} ) - \frac{{y ( 1 - {z}_{tp} )}^{2}}{2} ] [ ( 1 + {z}_{tp} ) + \frac{{y ( 1 + {z}_{tp} )}^{2}}{2} ] + {[ {z}_{tp} - \frac{y ( 1 - {z}_{tp}^{2} )}{2} ]}^{2} \cdot [ {t}^{2 w} + {t}^{- 2 w} ] - trace \{ {[ {M}_{OT , f} ] [ {M}_{OT , r} ]}^{- 1} \} & ( 3 )\end{matrix}$$

2. setting yₛₚ, zₜₚ in the self-calibration equations to 0, applying the measurement results from the offset series device calibrator and the offset shunt device calibrator in the self-calibration equations (1)-(3) and then using the Newton-Raphson method to allow the equations to converge thereby obtaining the values of γ, z, y (302);
3. using γ to find the values of yₛₚ, zₜₚ (303), where the equations for yₛₚ, zₜₚ can be respectively expressed as below:

yₛₚ=γΔl_{S}/2 (4)

zₜₚ=γΔl_{T}/2 (5)
4. placing the values of yₛₚ, zₜₚ acquired from STEP 3 into the self-calibration equations (1)-(3) conjunctively with the measurement results of the offset series device calibrator and the offset shunt device calibrator so as to get the values of γ′, z′, y′(304);
5. after having acquired the values of y′, y′ₛₚ and z′ₜₚ, performing operations on the error which can be written as ε=|y′ₛₚ−yₛₚ|/|yₛₚ|+|z′ₜₚ−zₜₚ|/|zₜₚ| (305);
6. determining that if the error ε is less than the required error (306), then starting evaluation of the error boxes and execution of de-embedding (308) (the de-embedding process allows to get the scattering parameter of the tested object, and in this case the characteristic impedance of the transmission line acts as the reference impedance); contrarily, suppose the error ε is still greater than the required error, returning to STEP 3 for repeating the aforementioned operations (whereas substituting original γ with y′, substituting original z with z′ and substituting original y with y′) (307), until the error ε becomes less than the required error; and
7. finally, using y′ to figure out Z_{C} and performing transmission line reference impedance conversion from Z_{C} to Z₀ (typically 50Ω), thereby acquiring the scattering parameter of the actual tested object based on the reference impedance of Z₀ (309).

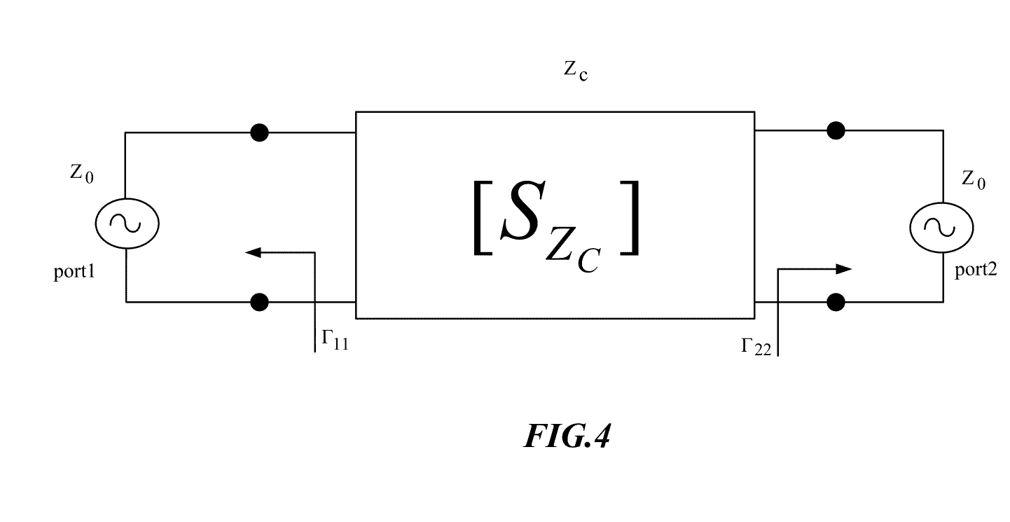

Refer next to FIG. 4, wherein an architecture diagram for the dual-port network of integral measurement is shown, and it should be noted that the characteristic impedance of the transmission lines in the network is Z_{C}, the characteristic impedance of the signal emitted from the network analyzer is Z₀, and the characteristic impedance can be converted from Z_{C} to Z₀ by means of a conversion relationship equation thus obtaining the scattering parameter of the actual tested object, wherein the conversion relationship equation can be written as below:

$$[ {D}_{{Z}_{0}} ] = \frac{1}{1 - {Γ}^{2}} [ \begin{matrix}1 & Γ \\ Γ & 1\end{matrix} ] \cdot [ {D}_{{Z}_{C}} ] \cdot [ \begin{matrix}1 & - Γ \\ - Γ & 1\end{matrix} ] , \qquad ( 6 )$$

in which [D_{Z}_{₀}] and [D_{Z}_{_{C}}] respectively indicates the transmission matrix before and after conversion, with γ defined as:

$$Γ = \frac{{Z}_{C} - {Z}_{0}}{{Z}_{C} + {Z}_{0}} . \qquad ( 7 )$$

It should be noted that the symbol “M” in the self-calibration equations denotes the transmission matrix of the measurement, wherein the subscript f, r respectively represents the forward and the reverse transmission matrix.

It should be also noted that, in STEP 7 of the calibration flowchart, suppose it is needed to convert the reference impedance to the conventional 50Ω, the characteristic impedance of the transmission line is required, so that it is possible to use the direct current (DC) resistance measurement value of the offset series device calibrator to obtain the reference impedance in the transmission line through the following equation, thus finally getting the scattering parameter of the actual tested object based on the 50Ω reference impedance.

$$\begin{matrix}{Z}_{C} = γ / ( j2π fC ) , & ( 8 ) \\ {C = Re \{ \frac{{S}_{22} γ}{j π f ( 1 - {S}_{22} ) {R}_{d c , Offset \text{-} series}} \} \vert}_{f < 1 GH z } . & ( 9 )\end{matrix}$$

From the above-said descriptions, it can be seen that the DC resistance measurement value of the offset series device calibrator can be applied to find out the characteristic impedance in the transmission line; then placing the measurement results into the mathematical matrixes to calculate the non-ideal effects resulting from the probe head, metal pads and internal metal signal transmission lines thereby successfully completing the broadband calibration measurement.

Compared with prior art, the measurement structure for RF scattering parameter measurement applying two calibrators and the calibration method thereof provided by the present invention can offer the following advantages:
1. the present invention enables calibration and de-embedment processes in the one-tier measurement of radio frequency scattering parameter for semiconductor wafer devices or other substrate devices, and also allows self-calculation of the characteristic impedance in the transmission line;
2. the present invention needs only to apply two calibrators to effectively complete broadband measurements and uses the known conditions offered by the calibrators to solve the same or more numbers of unknown variables in order to achieve the objective of self-calibration;
3. the calibration method according to the present invention features convenience in fabrication and simplicity, so it is not required to apply expensive materials, but only exploit the characteristics of series and shunt resistor connections for calibrating to a sufficient frequency bandwidth, and all characteristic parameters can be obtained though the self-calibration process as well.

Through the aforementioned detailed descriptions for the preferred embodiments according to the present invention, it is intended to better illustrate the characteristics and spirit of the present invention rather than restricting the scope of the present invention to the preferred embodiments disclosed in the previous texts. On the contrary, the objective is to encompass all changes and effectively equivalent arrangements within the scope of the present invention as delineated in the following claims of the present application.

What is claimed is:

1. A measurement structure for radio frequency (RF) scattering parameter measurement applying two calibrators, which uses a microwave probe as the contact interface for microwave signal transmissions, wherein the microwave probe at least includes a ground and a signal end, and the measurement structure for radio frequency scattering parameter measurement applying two calibrators comprises:
an offset series device calibrator, in which the microwave probe contacts the offset series device calibrator, and the offset series device calibrator consists of two transmission lines, an offset transmission line and a series resistor, in which the offset transmission line and the series resistor are connected between the two transmission lines, and the transmission lines are connected to the signal end of the microwave probe thereby performing measurements on the device characteristics of the series resistor;
an offset shunt device calibrator, in which the microwave probe contacts the offset shunt device calibrator, and the offset shunt device calibrator consists of two transmission lines, an offset transmission line and a shunt resistor, in which the offset transmission line and the shunt resistor are connected between the two transmission lines, and the transmission lines are connected to the signal end of the microwave probe thereby performing measurements on the device characteristics of the shunt resistor; and
a tested object measuring instrument, in which the microwave probe contacts the tested object measuring instrument, and the tested object measuring instrument consists of two transmission lines and a tested object, in which the tested object is connected between the two transmission lines and the transmission lines are connected to the signal end of the microwave probe thereby performing measurements on the device characteristics of the tested object.

2. The measurement structure for radio frequency scattering parameter meaurement applying two calibrators according to claim 1, wherein the length of the transmission lines for the offset series device calibrator and the offset shunt device calibrator is equal to the one of the transmission line for the tested object measuring instrument.

3. The measurement structure for radio frequency scattering parameter measurement applying two calibrators according to claim 1, wherein the offset series device calibrator, the offset shunt device calibrator and the tested object measuring instrument are applicable to silicon substrates, compound semiconductor substrates, ceramic substrates or epoxy glass fiber board substrates.

4. The measurement structure for radio frequency scattering parameter measurement applying two calibrators according to claim 1, wherein the offset series device calibrator, the offset shunt device calibrator and the tested object measuring instrument can apply the coplanar waveguide or the microstrip as the connection transmission line.

5. The measurement structure for radio frequency scattering parameter measurement applying two calibrators according to claim 1, wherein the microwave probe is a type of high frequency probe which can be characterized as G-S-G-S-G, G-S-S-G, G-S-G or G-S.

6. A calibration method for radio frequency scattering parameter measurement applying two calibrators, in which the method uses two calibrators, a tested object measuring instrument and equations of three variables, wherein the two calibrators and the tested object measuring instrument have the identical error boxes and the scattering parameter matrixes of the error boxes can be obtained by the calibration method such that, after connecting a tested electronic device onto the tested object measuring instrument, it is possible to perform operations on uncorrected measurement data thereby obtaining the radio frequency scattering parameter of the tested object.

7. The calibration method for radio frequency scattering parameter measurement applying two calibrators according to claim 6, wherein the self-calibration can be achieved which is intended to deduct errors introduced during measurements, in which the characteristics of such errors can be expressed with mathematical models, and, after measurements by the offset series device calibrator and the offset shunt device calibrator, all error parameters can be solved, thereby obtaining the errors required to be calibrated through operations and further calculating the parameters of the actual tested object.
